(19) United States
(12) Patent Application Publication
(10) Pub. No.: US 2024/0425409 A1
(43) Pub. Date: Dec. 26, 2024

(54) ANTI-SPARKLE SUBSTRATES, DISPLAY DEVICES, AND METHODS OF MAKING THE SAME

(71) Applicant: CORNING INCORPORATED, CORNING, NY (US)

(72) Inventors: Lars Martin Otfried Brusberg, Corning, NY (US); Cameron Robert Nelson, Agoura Hills, CA (US)

(21) Appl. No.: 18/738,614

(22) Filed: Jun. 10, 2024

Related U.S. Application Data
(60) Provisional application No. 63/521,944, filed on Jun. 20, 2023.

(51) Int. Cl. C03C 21/00; B24C 1/04; C03C 15/00; G02B 1/118; G03F 7/00

(52) U.S. Cl. CPC C03C 21/005; B24C 1/04; G02B 1/118; C03C 15/00; G03F 7/0007

(57) ABSTRACT

Anti-sparkle substrates include a plurality of features extending from a first major surface of the anti-sparkle substrate. In aspects, a feature of the plurality of features includes a feature concentration of one or more of silver, rubidium, or cesium that is non-zero at the first major surface and is greater than a corresponding concentration of a region of the first major surface excluding the plurality of features. In aspects, a feature of the plurality of features includes a gradient refractive index profile. A feature refractive index of the feature at the first major surface is greater than a substrate refractive index by about 0.03 or more. Methods include exposing a plurality of portions of a first major surface of a substrate to a source of one or more of silver ions, rubidium ions, or cesium ions to form a plurality of features in that include the plurality of portions.

This application claims the benefit of priority under 35 U.S.C. § 119 of U.S. Provisional Application Ser. No. 63/521,944 filed on Jun. 20, 2023, the content of which is relied upon and incorporated herein by reference in its entirety.

### FIELD

The present disclosure relates generally to anti-sparkle substrates, display devices, and methods of making the same and, more particularly, anti-sparkle substrates and display devices including anti-sparkle substrates with a plurality of features and methods of making the same.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), laser phosphor displays (LPDs), or the like. It is known to provide an anti-glare surface on glass substrates. However, an interaction between the anti-glare surface and a pixelated display can lead to sparkle, which is an undesirable grainy appearance and/or variations in the appearance of an image produced by the display device, for example, at a pixel-level size scale. Consequently, there is a desire to develop display devices that can mitigate sparkle.

### SUMMARY

There is set forth herein an anti-sparkle substrate and display devices including anti-sparkle substrates that can reduce a sparkle thereof by providing a plurality of features as part of the anti-sparkle substrate. The plurality of features can be integral to the anti-sparkle substrate, which can simplify assembly and/or alignment of elements in a resulting display device. Providing the anti-sparkle substrate as a glass-based substrate and/or ceramic-based substrate can facilitate the formation of the plurality of features (e.g., introduction of one or more of silver ions, cesium ions, rubidium ions, or combinations thereof), decrease a color shift of the display device (e.g., as a result of aging), increase a damage resistance, and/or increase a flexibility of the display device.

Reducing a sparkle through the anti-sparkle substrate of the present disclosure and increase a uniformity of light emitted from the display device, as perceived by a viewer of a display device, and/or increase an aesthetic appeal of the resulting display device by reducing the perceived graininess associated with sparkle. Without wishing to be bound by theory, the plurality of features can locally change a phase of light propagating through a feature of the plurality of features as compared to features propagating through the substrate but not a feature. Changing the phase of light can control destructive interference of light. For example, when the phase change is 180° or π radians (i.e., half the wavelength of light from a whole number (including 0) multiple of the wavelength of light) the light can completely cancel out. The effective phase change can be equal to an integral of a difference in the feature refractive index profile over the depth and the bulk refractive index of the substrate. Consequently, the plurality of features (e.g., including a gradient refractive index, and/or gradient concentration of silver, cesium, and/or rubidium) can function as a diffractive grating. A diffractive grating can produce light beams propagating at various diffraction orders with the angle (θ) between diffraction orders determined by a sub-pixel pitch (p), a spacing between the pixelated display and the plurality of features (L), a refractive index of the substrate (n), the wavelength of light (λ), and the feature pitch (Λ). For example, the relationship: Λ=λ/(n*sin(θ)), where tan(θ)=p/L. The diffraction induced by the plurality of features can reduce sparkle by reducing a contrast between bright spots (e.g., where light from a pixel would naturally be perceived by a user) and spaces therebetween since the diffractive orders (e.g., principally the first diffractive order) can increase the intensity of light therebetween. For example, the diffractive order can correspond to virtual images that can be perceived by a user of the display device as corresponding to the other sub-pixels of the pixel and/or other sub-pixels to provide a more uniform brightness (e.g., light intensity) of the corresponding light wavelength. Further, the gradient concentration profile and/or gradient refractive index profile of a feature of the plurality of features (e.g., as compared to a step profile of concentration and/or refractive index) can reduce a reflection (e.g., specular reflection) of ambient light incident on the second major surface and through the substrate that could otherwise be perceived by a user of the display device as washing out the display, additional bright spots, and/or refracted rainbows that can be distracting.

Some example aspects of the disclosure are described below with the understanding that any of the features of the various aspects may be used alone or in combination with one another.

Aspect 1. An anti-sparkle substrate comprising:
a plurality of features extending from a first major surface of the anti-sparkle substrate, a feature of the plurality of features comprising a gradient refractive index profile extending from the first major surface to a depth, a feature refractive index of the feature at the first major surface is greater than a substrate refractive index of a region of the first major surface excluding the plurality of features by about 0.03 or more,
wherein the anti-sparkle substrate is a glass-based material or a ceramic-based material.

Aspect 2. The anti-sparkle substrate of aspect 1, wherein the feature refractive index is greater than the substrate refractive index by from 0.05 to 0.10.

Aspect 3. The anti-sparkle substrate of any one of aspects 1-2, wherein the feature comprises a non-zero concentration of silver at the first major surface.

Aspect 4. The anti-sparkle substrate of any one of aspects 1-3, wherein the comprising a feature concentration of one or more of silver, rubidium, or cesium, the feature concentration is non-zero at the first major surface, and the feature concentration is greater than a concentration of one or more of silver, rubidium, or cesium of the region of the first major surface excluding the plurality of features.

Aspect 5. An anti-sparkle substrate comprising:
a plurality of features extending from a first major surface of the anti-sparkle substrate to a depth, a feature of the plurality of features comprising a feature concentration of one or more of silver, rubidium, or cesium, the feature concentration is non-zero at the first major surface, and the feature concentration is greater than a concentration of one or more of silver, rubidium, or cesium of a region of the first major surface excluding the plurality of features.

Aspect 6. The anti-sparkle substrate of claim 5, wherein a feature refractive index of the feature at the first major surface is greater than a substrate refractive index of the region of the first major surface excluding the plurality of features by from 0.01 to 0.12.

Aspect 7. The anti-sparkle substrate of claim 6, wherein the feature refractive index is greater than the substrate refractive index by from 0.03 to 0.10.

Aspect 8. The anti-sparkle substrate of any one of claims 6-7, wherein the feature of the plurality of features comprising a gradient refractive index profile extending from the first major surface to the depth.

Aspect 9. The anti-sparkle substrate of any one of aspects 4-8, wherein a concentration profile of the feature is a gradient from the feature concentration at the first major surface to a bulk concentration at the depth, the feature concentration is greater than the bulk concentration, and the concentration profile and the bulk concentration is of one or more of silver, rubidium, or cesium.

Aspect 10. The anti-sparkle substrate of any one of aspects 1-4 or 6-9 inclusive, wherein the feature refractive index is in a range from about 1.55 to about 1.60.

Aspect 11. The anti-sparkle substrate of any one of aspects 1-4 or 8 inclusive, wherein an integral of a difference in the gradient refractive index profile of the feature from the first major surface to the depth and a substrate refractive index profile of a portion excluding the plurality of features is in a range from about 200 nanometers to about 350 nanometers.

Aspect 12. The anti-sparkle substrate of any one of aspects 1-11, wherein the depth is in a range from about 8 micrometers to about 30 micrometers.

Aspect 13. The anti-sparkle substrate of aspect 12, wherein the depth is in a range from about 10 micrometers to about 15 micrometers.

Aspect 14. The anti-sparkle substrate of any one of aspects 1-13, wherein a maximum dimension of the feature on the first major surface is in a range from about 5 micrometers to about 20 micrometers.

Aspect 15. The anti-sparkle substrate of any one of aspects 1-14, wherein a spacing between an adjacent pair of features of the plurality of features is in a range from about 8 micrometers to about 30 micrometers, and the spacing is measured from a center of a first feature of the adjacent pair of features to a center of a second feature of the adjacent pair of features.

Aspect 16. The anti-sparkle substrate of aspect 15, wherein the spacing is in a range from about 10 micrometers to about 20 micrometers.

Aspect 17. The anti-sparkle substrate of any one of aspects 1-16, wherein a percentage of a total feature surface area of the plurality of features on the first major surface to a total surface area of the first major surface is in a range from about 35% to about 75%.

Aspect 18. The anti-sparkle substrate of aspect 17, wherein the percentage of the total feature surface area to the total surface area is in a range from about 40% to about 60%.

Aspect 19. The anti-sparkle substrate of any one of aspects 1-18, wherein the plurality of features are integral to the anti-sparkle substrate.

Aspect 20. The anti-sparkle substrate of any one of aspects 1-19, wherein a reflectance of light incident on a second major surface of the anti-sparkle substrate opposite the first major surface is less than 0.001%.

Aspect 21. The anti-sparkle substrate of any one of aspects 1-19, wherein a second major surface of the anti-sparkle substrate comprises a textured surface, the second major surface opposite the first major surface.

Aspect 22. The anti-sparkle substrate of aspect 21, wherein the anti-sparkle substrate exhibits a sparkle, as measured by pixel power deviation reference (PPDr), in a range from about 1% to 3%.

Aspect 23. The anti-sparkle substrate of aspect 22, wherein the sparkle is in a range from about 1.5% to about 2.5%.

Aspect 24. A display device comprising:
a pixelated display unit;
an antiglare layer; and
the anti-sparkle substrate of any one of aspects 1-20, positioned between the pixelated display unit and the antiglare layer.

Aspect 25. The display device of aspect 24, wherein the display device exhibits a sparkle, as measured by pixel power deviation reference (PPDr), in a range from about 1% to 3%.

Aspect 26. The display device of aspect 25, wherein the sparkle is in a range from about 1.5% to about 2.5%.

Aspect 27. The display device of any one of aspects 25-26, wherein a reference sparkle of another display device with another substrate instead of the anti-sparkle substrate without the plurality of features is greater than the sparkle of the display device by about 30% or more.

Aspect 28. A method of making an anti-sparkle substrate comprising:
exposing a plurality of portions of a first major surface of a substrate to a source of one or more of silver ions, rubidium ions, or cesium ions to form a plurality of features in the substrate, wherein the plurality of features include the plurality of portions, and the plurality of features extend from the first major surface of a depth.

Aspect 29. The method of aspect 28, wherein the exposing comprises contacting the plurality of portions with a molten salt solution comprising from 0.1 wt % to 20 wt % of one or more of silver nitrate, rubidium nitrate, or cesium nitrate.

Aspect 30. The method of aspect 29, wherein the molten salt solution contacts the plurality of portions for from about 1 minute to about 4 hours.

Aspect 31. The method of aspect 30, wherein the molten salt solution contacts the plurality of portions for from about 2 minutes to about 10 minutes.

Aspect 32. The method of any one of aspects 28-31, wherein the exposing the plurality of portions exposes the plurality of portions to a source of silver ions.

Aspect 33. The method of any one of aspects 28-32, further comprising, before the exposing, disposing a mask on at least the first major surface of the substrate, and patterning the mask to expose the plurality of portions.

Aspect 34. The method of any one of aspects 28-33, wherein a feature of the plurality of features comprising a feature concentration of one or more of silver, rubidium, or cesium, the feature concentration is non-zero at the first major surface, and the feature concentration is greater than a concentration of one or more of silver, rubidium, or cesium of a region of the first major surface excluding the plurality of features.

Aspect 35. The method of any aspect 34, wherein a concentration profile of the feature is a gradient from the feature concentration at the first major surface to a bulk concentration at the depth, the feature concentration is greater than the bulk concentration, and the concentration profile and the bulk concentration is a concentration of one or more of silver, rubidium, or cesium.

Aspect 36. The method of any one of aspects 28-35, wherein a feature refractive index of the feature at the first major surface is greater than a substrate refractive index of a region of the first major surface excluding the plurality of features by from 0.01 to 0.12.

Aspect 37. The method of aspect 36, wherein the feature refractive index is greater than the substrate refractive index by from 0.03 to 0.10.

Aspect 38. The method of any one of aspects 28-37, wherein the feature of the plurality of features comprising a gradient refractive index profile extending from the first major surface to the depth.

Aspect 39. The method of aspect 38, wherein an integral of a difference in the gradient refractive index profile of the feature from the first major surface to the depth and a substrate refractive index profile of a portion excluding the plurality of features is in a range from about 200 nanometers to about 350 nanometers.

Aspect 40. The method of any one of aspects 28-39, wherein the depth is in a range from about 8 micrometers to about 30 micrometers.

Aspect 41. The method of claim 40, wherein the depth is in a range from about 10 micrometers to about 15 micrometers.

Aspect 42. The method of any one of aspects 28-41, wherein a maximum dimension of the feature on the first major surface is in a range from about 5 micrometers to about 20 micrometers.

Aspect 43. The method of any one of aspects 28-42, wherein a spacing between an adjacent pair of features of the plurality of features is in a range from about 8 micrometers to about 30 micrometers, and the spacing is measured from a center of a first feature of the adjacent pair of features to a center of a second feature of the adjacent pair of features.

Aspect 44. The method of aspect 43, wherein the spacing is in a range from about 10 micrometers to about 20 micrometers.

Aspect 45. The method of any one of aspects 28-44, wherein a percentage of a total feature surface area of the plurality of features on the first major surface to a total surface area of the first major surface is in a range from about 35% to about 75%.

Aspect 46. The method of aspect 45, wherein the percentage of the total feature surface area to the total surface area is in a range from about 40% to about 60%.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example display device including an anti-sparkle substrate in accordance with aspects;

FIG. 2 is a schematic view of an anti-sparkle substrate in accordance with aspects;

FIG. 3 is a cross-sectional view of the anti-sparkle substrate along line 3-3 of FIG. 1 or FIG. 2 in accordance with aspects;

FIG. 4 is a cross-sectional view of the anti-sparkle substrate along line 4-4 of FIG. 1 or FIG. 2 in accordance with aspects;

FIG. 5 schematically illustrates a refractive index profile in a feature of the anti-sparkle substrate in accordance with aspects;

FIG. 6 schematically illustrates a concentration profile of silver in a feature of the anti-sparkle substrate in accordance with aspects;

FIG. 7 is a flow chart illustrating example methods of making an anti-sparkle substrate in accordance with aspects of the disclosure;

FIGS. 8-11 schematically illustrate steps in method of making an anti-sparkle substrate in accordance with aspects of the disclosure;

FIGS. 12-15 schematically illustrate sparkle produced for an anti-sparkle substrate with various depths for refractive index difference of 0.01, 0.03, 0.07, and 0.1, respectively corresponding to Examples 1-4, respectively;

FIG. 16 schematically illustrates bidirectional transmittance distribution function (BTDF) curves for Example 5 and Comparative Example AA; and

FIG. 17 schematically illustrates bidirectional reflectance distribution functions (BRDF) curves for Example 5 and Comparative Example AA.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts. However, claims may encompass many different aspects of various aspects and should not be construed as limited to the aspects set forth herein.

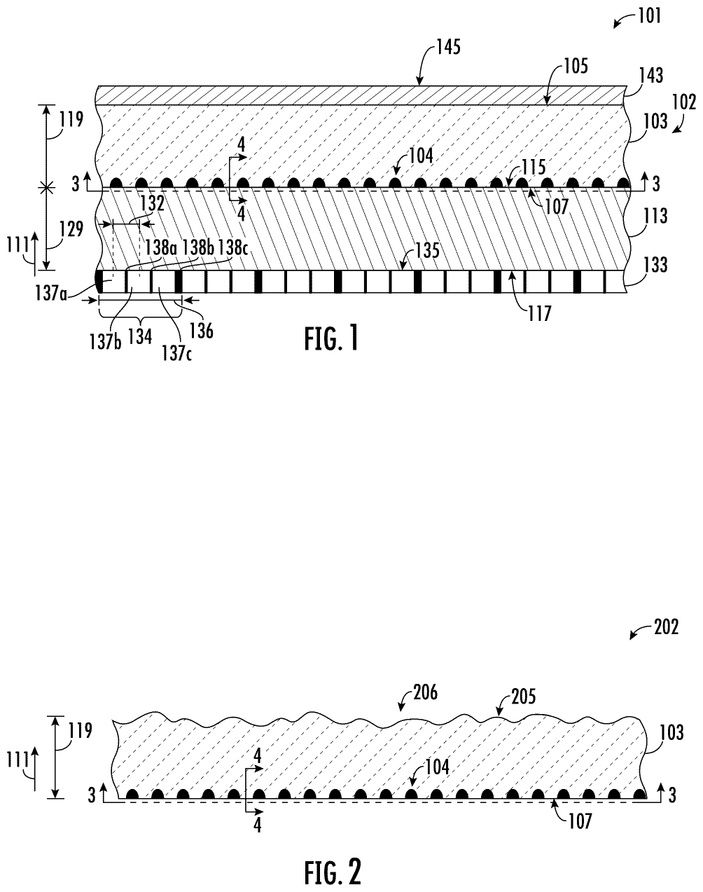

FIGS. 1-2 illustrate schematic views of a anti-sparkle substrate 102 and 202 including a plurality of features 104 in accordance with aspects of the disclosure. FIG. 1 illustrates a schematic view of a display device 101 including the anti-sparkle substrate 202. Unless otherwise noted, a discussion of features of aspects of one display device, anti-sparkle substrate, and/or feature of the plurality of features can apply equally to corresponding features of any aspects of the disclosure. For example, identical part numbers throughout the disclosure can indicate that, in some aspects, the identified features are identical to one another and that the discussion of the identified feature of one aspect, unless otherwise noted, can apply equally to the identified feature of any of the other aspects of the disclosure.

As shown in FIGS. 1-2, the anti-sparkle substrate 102 or 202 comprises a substrate 103. In aspects, the substrate can comprise a glass-based material and/or a ceramic-based material.

As used herein, “glass-based” material includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion-exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. “Glass-ceramics” include materials produced through controlled crystallization of glass. In aspects, glass-ceramics have about 1% to about 99% crystallinity. Exemplary aspects of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. The glass-ceramic substrates may be strengthened using the chemical strengthening processes, for example, an MAS-system glass-ceramic material may be strengthened in Li₂SO₄ molten salt.

As used herein, “ceramic-based” includes both ceramics and glass-ceramics, wherein glass-ceramics have one or more crystalline phases and an amorphous, residual glass phase. Ceramic-based materials can be strengthened (e.g., chemically strengthened). In aspects, a ceramic-based material can be formed by heating a glass-based material to form ceramic (e.g., crystalline) portions. In further aspects, ceramic-based materials can comprise one or more nucleating agents that can facilitate the formation of crystalline phase(s). In aspects, ceramic-based materials can comprise one or more oxides, nitrides, oxynitrides, carbides, borides, and/or silicides. Example aspects of ceramic oxides include zirconia (ZrO₂), zircon (ZrSiO₄), an alkali-metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example aspects of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example aspects of oxynitride ceramics include silicon oxynitride, aluminum oxynitride, and a silicon-aluminum oxynitride.

In aspects, the substrate 103 can comprise a pencil hardness of 8H or more, for example, 9H or more. As used herein, pencil hardness is measured in accordance with ASTM D 3363-20 using standard lead graded pencils. Throughout the disclosure, an elastic modulus (e.g., Young's modulus) and/or a Poisson's ratio is measured using ISO 527-1:2019. In aspects, the substrate 103 can comprise an elastic modulus of about 10 GigaPascal (GPa) or more, about 30 GPa or more, about 50 GPa or more, about 60 GPa or more, about 70 GPa or more, about 200 GPa or less, about 150 GPa or less, about 120 GPa or less, 100 GPa or less, about 90 GPa or less, or about 80 GPa or less. In aspects, the substrate 103 can comprise an elastic modulus in a range from about 10 GPa to about 200 GPa, from about 30 GPa to about 150 GPa, from about 50 GPa to about 120 GPa, from about 60 GPa to about 100 GPa, from about 60 GPa to about 90 GPa, from about 70 GPa to about 90 GPa, or any range or subrange therebetween.

In aspects, the substrate 103 can be optically transparent. As used herein, “optically transparent” or “optically clear” means an average transmittance of 70% or more in the wavelength range of 400 nm to 700 nm through a 1.0 mm thick piece of a material. In aspects, an “optically transparent material” or an “optically clear material” may have an average transmittance of 75% or more, 80% or more, 85% or more, or 90% or more, 92% or more, 94% or more, 96% or more in the wavelength range of 400 nm to 700 nm through a 1.0 mm thick piece of the material. The average transmittance in the wavelength range of 400 nm to 700 nm is calculated by measuring the transmittance of whole number wavelengths from about 400 nm to about 700 nm and averaging the measurements.

As shown in FIGS. 1-2, the substrate 103 of the anti-sparkle substrate 102 or 202 can comprise a first major surface 107 and a second major surface 105 or 205 opposite the first major surface 107. In aspects, as shown in FIG. 1, the second major surface 105 can comprise a planar surface, for example, when an anti-glare layer 143 (discussed below) is disposed thereon. Alternatively, as shown in FIG. 2, the second major surface 205 can comprise a textured surface 206 (discussed below), which can comprise any one or more of the aspects discussed below for the anti-glare layer 143. In aspects, as shown in FIGS. 1-2, the first major surface 107 can be planar, although non-planar surface can be provided in other aspects. As shown in FIGS. 1-2, a substrate thickness 119 is measured in a thickness direction 111 as an average distance between the first major surface 107 and the second major surface 105 or 205 averaged over the first major surface 107. In aspects, the substrate thickness 119 be about 25 micrometers (μm) or more, about 80 μm or more, about 100 μm or more, about 125 μm or more, about 150 μm or more, about 200 μm or more, about 500 μm or more, about 700 μm or more, about 5 millimeters (mm) or less, about 3 mm or less, about 2 mm or less, about 1 mm or less, about 800 μm or less, about 500 μm or less, about 300 μm or less, about 200 μm or less, about 180 μm or less, or about 160 μm or less. In aspects, the substrate thickness 119 can be less in a range from about 25 μm to about 5 mm, from about 25 μm to about 3 mm, from about 25 μm to about 2 mm, from about 80 μm to about 1 mm, from about 80 μm to about 800 μm, from about 100 μm to about 500 μm, from about 100 μm to about 300 μm, from about 125 μm to about 200 μm, from about 150 μm to about 160 μm, or any range or subrange therebetween. In aspects, the substrate thickness 119 can be about 500 μm or more, for example, from about 500 μm to about 3 mm, from about 700 μm to about 2 mm, from about 700 μm to about 1 mm, or any range or subrange therebetween. In aspects, the substrate thickness 119 can be about 500 μm or less, for example, from about 25 μm to about 500 μm, from about 25 μm to about 300 μm, from about 80 μm to about 200 μm, from about 100 μm to about 200 μm, or any range or subrange therebetween.

As shown in FIGS. 1-2, the anti-sparkle substrate 102 or 202 has a plurality of features 104 extending from the first major surface 107. In aspects, as shown in FIG. 4, the plurality of features (e.g., features 403a-403b and/or 413a-413b) extend to a depth 405 from the first major surface 107 (e.g., in the thickness direction 111). For example, as shown, the plurality of features 104 can be integral to the anti-sparkle substrate 102 or 202. In aspects, the depth 405 can be about 8 μm or more, about 9 μm or more, about 10 μm or more, about 12 μm or more, about 15 μm or more, about 30 μm or less, about 25 μm or less, about 20 μm or less, about 18 μm or less, or about 15 μm or less. In aspects, the depth 405 can be in a range from about 8 μm to about 30 μm, from about 9 μm to about 25 μm, from about 10 μm to about 20 μm, from about 10 μm to about 18 μm, from about 10 μm to about 15 μm, from about 12 μm to about 15 μm, or any range or subrange therebetween. As shown, the depth 405 of a feature 403a and 413a can correspond to a distance that an apex 404a and 414a is from the first major surface 107. In further aspects, the depth 405 can also correspond to an average depth of the plurality of features and/or the corresponding depths of the plurality of features can be substantially equal to the depth 405. As discussed below, providing a feature of the plurality of features with a depth within one or more of the above-mentioned ranges can reduce sparkle.

In aspects, as shown in FIG. 4, a shape of a profile in the thickness direction 111 of a feature 403a, 403b, 413a, and/or 413b of the plurality of features can be rounded or curvilinear. In further aspects, as shown, the shape of features 403a and 403b can be a semi-oval (e.g., semi-ovoid in three dimensions). In further aspects, as shown, the shape of features 413a and 413b can be a truncated semi-oval (e.g., a semi-frusto-ovoid in three dimensions). Without wishing to be bound by theory, the semi-oval shape can correspond to features generated from longer treatment times (in the methods discussed below) and/or faster diffusing ions than the corresponding aspects of a feature with the truncated semi-oval. In further aspects, as shown, the profile of the features 403a, 403b, 403a, and 413b can be symmetric about an plane extending through the apex 404a and 414a in the thickness direction 111 perpendicular to the cross-section shown in FIG. 4. In further aspects, although not shown, the shape of the features can be rotationally symmetric (e.g., 2 fold symmetry, 3 fold symmetric, 6 fold symmetric, substantially infinite symmetry) about an axis extending in the thickness direction 111 through the apex 404a or 414a.

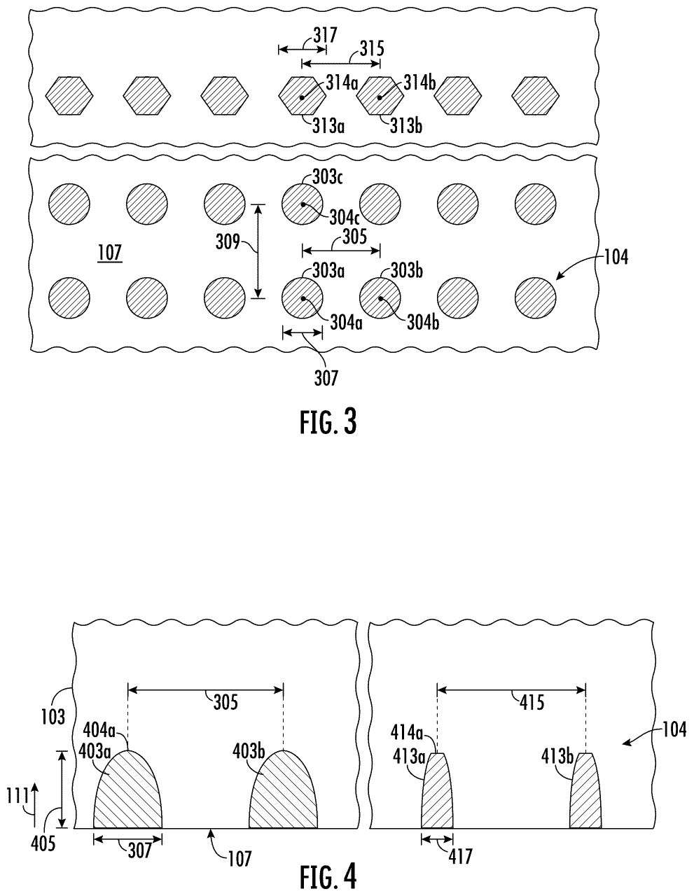

In aspects, as shown in FIG. 3, a portion of the first major surface 107 occupied by a feature (e.g., “footprint” of feature 303a-303c and/or 313a-313b) can be curved, polygonal, or curvilinear. In further aspects, as shown, the footprint of feature 303a-303c can be curved in an oval shape (e.g., circular). In further aspects, as shown, the footprint of feature 313a-313b can be polygonal (e.g., hexagonal), although rounded versions of polygons (i.e., curvilinear, rounded hexagons) are possible in further aspects.

As used herein, a “maximum dimension” of a feature on the first major surface refers to the longest linear distance from one end of the feature (e.g., footprint) to another end of the feature such that a line segment connecting the two ends is entirely within the feature (other than at the ends) along the first major surface. For example, as shown in FIG. 3, a maximum dimension 307 of a feature 303a comprising a circular footprint can be equal to the diameter of the corresponding circle. Also, as shown, the maximum dimension 317 of feature 313a can correspond to a distance between opposing vertices of the hexagonal footprint of feature 313a. The maximum dimension 307, 317, and 417 is depicted in FIGS. 3-4. In aspects, the maximum dimension 307, 317, or 417 of a feature 303a, 313a, 403a, or 413a in the first major surface 107 can be about 5 μm or more, about 7 μm or more, about 10 μm or more, about 12 μm or more, about 20 μm or less, about 18 μm or less, about 15 μm or less, or about 13 μm or less. In aspects, the maximum dimension of a feature in the first major surface can be in a range from about 5 μm to about 20 μm, from about 7 μm to about 18 μm, from about 10 μm to about 15 μm, from about 10 μm to about 13 μm, or any range or subrange therebetween. In further, a majority, substantially all, or all of the features of the plurality of features can be within one or more of the ranges mentioned above in this paragraph. In further, an average of the maximum dimension of the plurality of features can be within one or more of the ranges mentioned above in this paragraph. In further aspects, substantially all of the plurality of features can comprise substantially the same maximum dimension.

As used herein, a “spacings” between an adjacent pair of features is measured between the centroids of the corresponding features on the first major surface. For example, as shown in FIG. 3, a first spacing 305 is a distance between a centroid 304a of the feature 303a on the first major surface 107 and the centroid 304b of the feature 303b on the first major surface 107, where feature 303b is adjacent to feature 303a. As used herein, an adjacent pair of features refers to a pair of features with no features therebetween and the distance therebetween is the smallest of any corresponding distance between a feature of the adjacent pair of features and another feature within a 90° region centered on the distance between the adjacent pair of features. For example, as shown in FIG. 3, feature 303a and feature 303b form an adjacent pair of features and feature 303a and feature 303c form an adjacent pair of features since there is no other feature between the adjacent pair of features and a 90° region (i.e., 45° in each direction) does not have a feature closer to feature 303a than feature 303b or 303c (i.e., the feature diagonally positioned relative to feature 303a is further). Likewise, a second spacing 309 is a distance between a centroid 304a of the feature 303a on the first major surface 107 and the centroid 304c of the feature 303c on the first major surface 107, where feature 303c is adjacent to feature 303a. In further aspects, a direction of the first spacing 305 can be substantially perpendicular to a direction of the second spacing 309. In further aspects, the first spacing 305 can be substantially equal to the second spacing 309. For the polygonal features shown in FIG. 3, a first spacing 315 is a distance between a centroid 314a of the feature 313a on the first major surface 107 and a centroid 314b of the feature 313b on the first major surface 107, where feature 313a and feature 313b are adjacent features. With reference to FIG. 4, a first spacing 415 between feature 413a and feature 413b measured between the corresponding centroids, where feature 413a and feature 413b are adjacent features. In aspects, as shown in FIG. 3, a set of the features of the plurality of features 104 can be arranged in a row. In further aspects, the distance between each adjacent pair of features in the row can be substantially the same. In aspects, the first spacing 305, 315, or 415 and/or the second spacing 309 can be about 8 μm or more, about 9 μm or more, about 10 μm or more, about 12 μm or more, about 15 μm or more, about 17 μm or more, about 30 μm or less, about 25 μm or less, about 22 μm or less, about 20 μm or less, about 18 μm or less, about 15 μm or less, or about 12 μm or less. In aspects, the first spacing and/or the second spacing can be in a range from about 8 μm to about 30 μm, from about 9 μm to about 25 μm, from about 10 μm to about 20 μm, from about 12 μm to about 18 μm, from about 15 μm to about 17 μm, or any range or subrange therebetween. In aspects, the first spacing and/or the second spacing can be less than or equal to a pitch of pixels and/or a pitch of sub-pixels in a pixelated display that the anti-sparkle substrate is configured to be used with (discussed below).

An area of a feature of the plurality of features corresponds to the portion of the first major surface occupied by the feature (occupied by the “footprint” of the feature). A total feature surface area is the sum of the area of each feature of the plurality of features on the first major surface. In aspects, a percentage of the total feature surface area of the plurality of features on the first major surface to a total surface area of the first major surface can be about 35% or more, about 40% or more, about 43% or more, about 45% or more, about 48% or more, about 50% or more, about 52% or more, about 75% or less, about 70% or less, about 65% or less, about 60% or less, about 58% or less, about 55% or less, about 52% or less, about 50% or less, or about 48% or less. In aspects, a percentage of the total feature surface area of the plurality of features on the first major surface to a total surface area of the first major surface can be in a range from about 35% to about 70%, from about 35% to about 65%, from about 40% to about 60%, from about 43% to about 57%, from about 45% to about 55%, from about 48% to about 52%, from about 48% to about 50%, or any range or subrange therebetween. In aspects, the percentage of the total feature surface area of the plurality of features on the first major surface to a total surface area of the first major surface can be greater than 50%, for example, in a range from greater than 50% to about 75%, from about 52% to about 70%, from about 52% to 65%, from about 55% to about 60%, or any range or subrange therebetween. In aspects, the percentage of the total feature surface area of the plurality of features on the first major surface to a total surface area of the first major surface can be less than 50%, from about 35% to less than 50%, from about 40% to about 48%, from about 42% to about 45%, or any range or subrange therebetween. Providing a ratio of the total feature area to the total surface area within one or more of the above-emphasized features can reduce sparkle, for example, providing a density of features that can create virtual images that can be perceived by a user as coming from additional sub-pixels, which can increase a uniformity of illumination of the display device.

Unless otherwise indicated, a refractive index is measured in accordance with ASTM E1967-19 using light comprising an optical wavelength of 589 nm. In aspects, a substrate refractive index of the substrate 103 of the anti-sparkle substrate 102 or 202 can be about 1.4 or more, about 1.45 or more, about 1.49 or more, about 1.5 or more, about 1.53 or more, about 1.55 or more, about 2 or less, about 1.8 or less, about 1.7 or less, about 1.65 or less, about 1.6 or less, about 1.57 or less, about 1.56 or less, or about 1.55 or less. In aspects, a substrate refractive index of the substrate 103 of the anti-sparkle substrate 102 or 202 can be in a range from about 1.4 to about 2, from about 1.45 to about 1.8, from about 1.45 to about 1.65, from about 1.45 to about 1.65, from about 1.5 to about 1.6, from about 1.5 to about 1.57, from about 1.53 to about 1.55, or any range or subrange therebetween. In aspects, the substrate refractive index can correspond to a refractive index of material at and/or near the first major surface 107 in a region excluding the plurality of features. In aspects, a bulk refractive index of the substrate 103 of the anti-sparkle substrate 102 or 202 can correspond to a refractive index of material at and/or near a midplane positioned midway between the first major surface 107 and the second major surface 105 or 205. In further aspects, the bulk refractive index can be within one or more of the refractive index ranges for the substrate refractive index. In further aspects, the surface refractive index can be greater than the bulk refractive index by about 0.01 or more, about 0.02 or more, about 0.03 or more, about 0.04 or more, about 0.05 or more, about 0.1 or less, about 0.8 or less, about 0.06 or less, or about 0.05 or less, for example, in a range from about 0.01 to about 0.1, from about 0.02 to about 0.08, from about 0.03 to about 0.08, from about 0.04 to about 0.06, or any range or subrange therebetween.

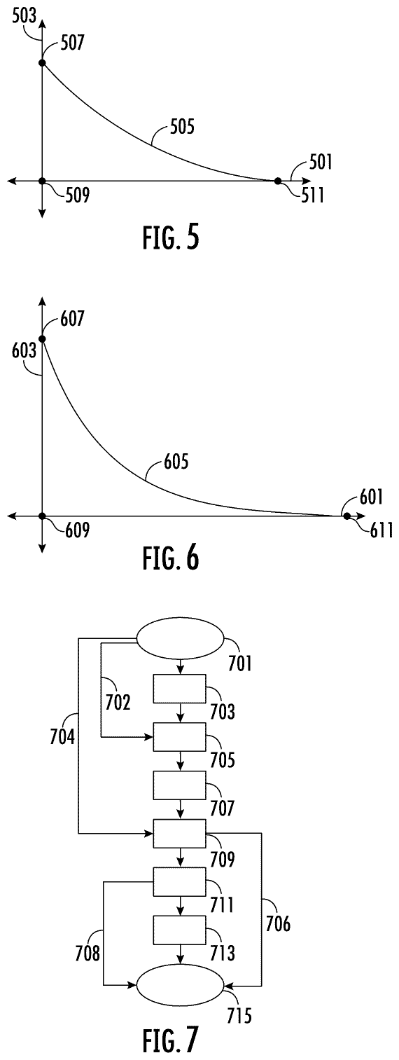

FIG. 5 schematically illustrates a refractive index profile of a feature of the plurality of features. The horizontal axis 501 corresponds to a distance in the thickness direction 111 from the first major surface 107, and the vertical axis 503 corresponds to a refractive index. On the horizontal axis 501, point 509 corresponds to the first major surface 107 (i.e., 0 distance). Curve 505 corresponds to the refractive index profile of the feature along the thickness direction 111, for example, taken along a line extending through the apex 404a and/or centroid 304a-304c or 314a-314b) thickness direction 111. Point 507 corresponds to a feature refractive index, which is the refractive index of the feature at the first major surface. Point 511 corresponds to the refractive index at the depth of the feature, where the refractive index can be substantially equal to the bulk refractive index. In aspects, as shown in FIG. 5, the feature of the plurality of features can comprise a gradient refractive index profile from the first major surface to the depth. As used herein, a “gradient refractive index” means that the refractive index of the feature continuously decreases as the distance from the first major surface increases.

In aspects, the feature refractive index (i.e., the refractive index of the feature at the first major surface) can be about 1.53 or more, about 1.55 or more, about 1.56 or more, about 1.57 or more, about 1.58 or more, about 1.65 or less, about 1.63 or less, about 1.6 or less, about 1.59 or less, or about 1.58 or less. In aspects, the feature refractive index can be in a range from about 1.53 to about 1.65, from about 1.53 to about 1.63, from about 1.55 to about 1.6, from about 1.56 to about 1.6, from about 1.57 to about 1.59, or any range or subrange therebetween. In aspects, the feature refractive index can be greater than the substrate refractive index (e.g., of a region of the first major surface excluding the plurality of features) by about 0.01 or more, about 0.02 or more, about 0.03 or more, about 0.04 or more, about 0.05 or more, about 0.06 or more, about 0.07 or more, about 0.12 or less, about 0.11 or less, about 0.1 or less, about 0.09 or less, about 0.08 or less, about 0.07 or less, about 0.06 or less, or about 0.05 or less. In aspects, the feature refractive index can be greater than the substrate refractive index by an amount in a range from about 0.01 to about 0.12, from about 0.02 to about 0.11, from about 0.03 to about 0.1, from about 0.04 to about 0.1, from about 0.05 to about 0.1, from about 0.05 to about 0.09, from about 0.06 to about 0.08, or any range or subrange therebetween. As discussed below, providing a feature refractive index and/or a difference of the feature refractive index relative to the substrate refractive index can cause destructive interference of light passing through the feature with other light transmitted through the substrate and/or functioning as a diffractive grating to reduce sparkle.

A feature can comprise an optical distance greater than a corresponding portion of the substrate without the feature, which can be measured as an integral of the difference between the feature refractive index profile and a refractive index profile of the substrate (excluding the plurality of features) from the first major surface to the depth of the feature. For example, the difference in optical distance can be measured as the area between the feature refractive index profile (e.g., curve 505) shown in FIG. 5 and a substrate refractive index profile (excluding the plurality of features). In aspects, the integral of the difference between the gradient refractive index profile of the feature from the first major surface to the depth and a substrate refractive index profile of a portion excluding the plurality of features can be about 200 nanometers (nm) or more, about 220 nm or more, about 250 nm or more, about 280 nm or more, about 300 nm or more, about 350 nm or less, about 320 nm or less, about 300 nm or less, about 280 nm or less, or about 250 nm or less. In aspects, the integral of the difference between the gradient refractive index profile of the feature from the first major surface to the depth and a substrate refractive index profile of a portion excluding the plurality of features can be in a range from about 200 nm to about 350 nm, from about 220 to about 320 nm, from about 250 nm to about 300 nm, from about 280 nm to about 300 nm, or any range or subrange therebetween.

In aspects, a feature of plurality of features comprises a non-zero concentration profile of one or more of silver, cesium, rubidium, or combinations thereof. In further aspects, a value of the concentration profile at the first major surface is non-zero. In even further aspects, a value of the concentration profile at or near the first major surface (e.g., feature concentration) can be a maximum value of the concentration profile. In further aspects, the concentration of the feature can be greater than a concentration of one or more of silver, cesium, rubidium, or combinations thereof in a region of the first major surface excluding the plurality of features. In further aspects, a concentration of one or more of silver, cesium, rubidium, or combinations thereof in a region of the first major surface excluding the plurality of features can be substantially zero. Providing silver, cesium, rubidium, and/or combinations thereof can increase a refractive index of the features relative to the substrate refractive index even at relatively low concentrations.

FIG. 6 schematically illustrates a concentration profile of a feature of the plurality of features. The horizontal axis 601 corresponds to a distance in the thickness direction 111 from the first major surface 107, and the vertical axis 603 corresponds to a concentration (e.g., of one or more of silver, cesium, rubidium, or combinations thereof; or of silver). On the horizontal axis 601, point 609 corresponds to the first major surface 107 (i.e., 0 distance). Curve 605 corresponds to the concentration profile of the feature along the thickness direction 111, for example, taken along a line extending through the apex 404a and/or centroid 304a-304c or 314a-314b) thickness direction 111. Point 607 corresponds to a feature concentration, which is the concentration (e.g., of one or more of silver, cesium, rubidium, or combinations thereof; or of silver) of the feature at the first major surface. Point 611 corresponds to the concentration at the depth of the feature, where the concentration can be substantially zero.

In further aspects, the feature comprises a non-zero concentration of silver at the first major surface. In even further aspects, the concentration of silver may be at a maximum at or near the first major surface. In even further aspects, the concentration of silver (e.g., feature concentration) in the feature can be greater than a concentration of silver in a region of the first major surface excluding the plurality of features. In even further aspects, a concentration of silver in a region of the first major surface excluding the plurality of features can be substantially zero.

In aspects, the substrate 103 may comprise one or compressive stress regions, for example, extending from the first major surface 107 and/or the second major surface 105 or 205. In aspects, the compressive stress region may be created by chemically strengthening the substrate. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the substrate can enable small (e.g., smaller than about 10 mm or less) bend radii because the compressive stress from the chemical strengthening can counteract the bend-induced tensile stress on the outermost surface of the substrate. A compressive stress region may extend into a portion of the substrate for a depth called the depth of compression. As used herein, depth of compression means the depth at which the stress in the chemically strengthened substrates described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate is generated by exchanging potassium ions into the substrate, a surface stress meter, for example, the FSM-6000 (Orihara Industrial Co., Ltd. (Japan)), is used to measure a depth of compression. Unless specified otherwise, compressive stress (including surface CS) is measured by surface stress meter (FSM) using commercially available instruments, for example, the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 75 μm, SCALP is used to measure the depth of compression and central tension (CT). Where the stress in the substrate is generated by exchanging both potassium and sodium ions into the glass, and the article being measured is thicker than about 75 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” (DOL) means the depth that the ions have exchanged into the substrate (e.g., sodium, potassium). Through the disclosure, when the central tension cannot be measured directly by SCALP (as when the article being measured is thinner than about 75 μm) the maximum central tension can be approximated by a product of a maximum compressive stress and a depth of compression divided by the difference between the thickness of the substrate and twice the depth of compression, wherein the compressive stress and depth of compression are measured by FSM.

In aspects, the substrate 103 may be chemically strengthened to form a first compressive stress region extending to a first depth of compression from the first major surface 107 (in addition to the plurality of features 104). In aspects, the substrate 103 may be chemically strengthened to form a second compressive stress region extending to a second depth of compression from the second major surface 105 or 205. In even further aspects, the first depth of compression (e.g., from the first major surface 107) and/or second depth of compression (e.g., from the second major surface 105) as a percentage of the substrate thickness 119 can be about 1% or more, about 5% or more, about 10% or more, about 30% or less, about 25% or less, or about 20% or less. In even further aspects, the first depth of compression and/or the second depth of compression as a percentage of the substrate thickness 119 can be in a range from about 1% to about 30%, from about 1% to about 25%, from about 5% to about 25%, from about 5% to about 20%, from about 10% to about 20%, or any range or subrange therebetween. In aspects, the first depth of compression and/or the second depth of compression can be about 1 μm or more, about 10 μm or more, about 50 μm or more, about 200 μm or less, about 150 μm or less, or about 100 μm or less. In aspects, the first depth of compression and/or the second depth of compression can be in a range from about 1 μm to about 200 μm, from about 1 μm to about 150 μm, from about 10 μm to about 150 μm, from about 50 μm to about 150 μm, from about 50 μm to about 100 μm, or any range or subrange therebetween. In aspects, the first depth of compression can be greater than, less than, or substantially the same as the second depth of compression. By providing a glass-based substrate and/or a ceramic-based substrate comprising a first depth of compression and/or a second depth of compression in a range from about 1% to about 30% of the first thickness, good impact and/or puncture resistance can be enabled.

In aspects, the substrate 103 can comprise a first depth of layer of one or more alkali metal ions associated with the first compressive stress region and/or a second depth of layer of one or more alkali metal ions associated with the second compressive stress region. In aspects, the first depth of layer and/or second depth of layer as a percentage of the substrate thickness 119 can be about 1% or more, about 5% or more, about 10% or more, about 15% or more, about 20% or more, about 35% or less, about 30% or less, about 25% or less, or about 22% or less. In aspects, the first depth of layer and/or second depth of layer as a percentage of the substrate thickness 119 can be in a range from about 1% to about 35%, from about 5% to about 35%, from about 5% to about 30%, from about 10% to about 30%, from about 10% to about 25%, from about 15% to about 25%, from about 15% to about 22%, from about 20% to about 22%, or any range or subrange therebetween. In aspects, the first depth of layer and/or second depth of layer can be about 1 μm or more, about 10 μm or more, about 50 μm or more, about 200 μm or less, about 150 μm or less, or about 100 μm or less. In aspects, the first depth of layer and/or second depth of layer of layer can be in a range from about 1 μm to about 200 μm, from about 1 μm to about 150 μm, from about 10 μm to about 150 μm, from about 50 μm to about 150 μm, from about 50 μm to about 100 μm, or any range or subrange therebetween.

In aspects, the first compressive stress region can comprise a maximum first compressive stress. In aspects, the second compressive stress region can comprise a maximum second compressive stress. In further aspects, the maximum first compressive stress and/or the maximum second compressive stress can be about 100 MegaPascals (MPa) or more, about 300 MPa or more, about 500 MPa or more, about 700 MPa or more, about 1,500 MPa or less, about 1,200 MPa or less, about 1,000 MPa or less, or about 900 MPa or less. In further aspects, the maximum first compressive stress and/or the maximum second compressive stress can be in a range from about 100 MPa to about 1,500 MPa, from about 100 MPa to about 1,200 MPa, from about 300 MPa to about 1,200 MPa, from about 300 MPa to about 1,000 MPa, from about 500 MPa to about 1,000 MPa, from about 700 MPa to about 1,000 MPa, from about 700 MPa to about 900 MPa, or any range or subrange therebetween. Providing a maximum first compressive stress and/or a maximum second compressive stress in a range from about 100 MPa to about 1,500 MPa can enable good impact and/or puncture resistance.

In aspects, the substrate 103 can comprise a central tension region positioned between the first compressive stress region and the second compressive stress region. In further aspects, the central tension region can comprise a maximum central tensile stress. In aspects, the maximum central tensile stress can be about 50 MPa or more, about 100 MPa or more, about 200 MPa or more, about 250 MPa or more, about 750 MPa or less, about 600 MPa or less, about 500 MPa or less, about 450 MPa or less, about 400 MPa or less, about 350 MPa or less, or about 300 MPa or less. In aspects, the maximum central tensile stress can be in a range from about 50 MPa to about 750 MPa, from about 50 MPa to about 600 MPa, from about 100 MPa to about 600 MPa, from about 100 MPa to about 500 MPa, from about 200 MPa to about 500 MPa, from about 200 MPa to about 450 MPa, from about 250 MPa to about 450 MPa, from about 250 MPa to about 350 MPa, from about 250 MPa to about 300 MPa, or any range or subrange therebetween.

In aspects, as shown in FIG. 1, the display device 101 can comprise an anti-glare layer 143 disposed on and/or disposed over the anti-sparkle substrate 102 (e.g., on the second major surface 105, opposite the plurality of features 104). In aspects, the anti-glare layer 143 can comprise an exterior surface 145 that may correspond to an exterior surface (e.g., user-facing surface) of the display device 101. In aspects, the anti-glare layer 143 can comprise a textured surface (e.g., exterior surface 145). In further aspects, the textured surface can comprise an irregular series of surface features generating a surface roughness. Without wishing to be bound by theory, the textured surface and/or irregular features can disrupt and/or reduce the intensity of specular reflection from the textured surface that would otherwise be associated with glare. Throughout the disclosure, a surface profile of the first surface area of the coating is measured over a test area of 2 μm by 2 μm as measured using atomic force microscopy (AFM), which is used to characterize the first surface area using the parameters defined in ISO 4287:1997. As used herein, surface roughness Ra is calculated as an arithmetical mean of the absolute deviation of a surface profile from an average position. In further aspects, a surface roughness Ra of the textured surface can be about 80 nm or more, about 100 nm or more, about 120 nm or more, about 150 nm or more, about 180 nm or more, about 200 nm or more, about 800 nm or less, about 500 nm or less, about 400 nm or less, about 300 nm or less, about 200 nm or less, or about 180 nm or less. In further aspects, the surface roughness Ra can be in a range from about 80 nm to about 800 nm, from about 100 nm to about 500 nm, from about 120 nm to about 400 nm, from about 150 nm to about 300 nm, from about 150 nm to about 200 nm, or any range or subrange therebetween. As discussed above with reference to FIG. 2, it is to be understood that the second major surface 105 can comprise the textured surface and the separate anti-glare layer shown in FIG. 1 can be omitted in other aspects.

In aspects, as shown in FIG. 1, the display device 101 can comprise an optical stack 113. In further aspects, as shown, the optical stack 113 can be positioned between the pixelated display 133 and the anti-sparkle substrate 102 (e.g., first major surface 107 of the substrate 103). For example, a third major surface 117 of the optical stack 113 can face and/or contact a surface 135 of the pixelated display, and/or a fourth major surface 115 can face and/or contact the first major surface 107 of the anti-sparkle substrate 102, where the fourth major surface 115 is opposite the third major surface 117. In further aspects, a stack thickness 129 of the optical stack 113 is defined as an average distance between the third major surface 117 and the fourth major surface 115. In even further aspects, the stack thickness 129 can be about 50 μm or more, about 100 μm or more, about 200 μm or more, about 500 μm or more, about 800 μm or more, about 1 mm or more, about 5 mm or less, about 4 mm or less, about 3 mm or less, about 2.5 mm or less, about 2 mm or less, about 1.5 mm or less, about 1 mm or less, about 500 μm or less, or about 200 μm or less. In aspects, the stack thickness 129 can be in a range from about 50 μm to about 5 mm, from about 100 μm to about 4 mm, from about 200 μm to about 4 μm, from about 500 μm to about 3 mm, from about 800 μm to about 3 mm, from about 1 mm to about 3 mm, from about 1.5 mm to about 2.5 mm, or any range or subrange therebetween. In aspects, the optical stack 113 can comprise one or more of a polarizer, a collimator, a diffuser, an optically clear adhesive, an electronic device (e.g., touch sensor), or combinations thereof.

As shown in FIG. 1, the display device 101 can include a pixelated display 133 comprising at least one pixel 134 including a plurality of sub-pixels 137a-137c. In aspects, a pixel of the at least one pixel 134 can comprise three sub-pixels 137a-137c, for example, a red sub-pixel (e.g., configured to emit light corresponding to a wavelength in a range from about 600 nm to about 660 nm), a green sub-pixel (e.g., configured to emit light corresponding to a wavelength in a range from about 500 nm to about 560 nm), and a blue-sub-pixel (e.g., configured to emit light corresponding to a wavelength in a range from about 430 nm to about 490 nm), although other configurations are possible in other aspects. In aspects, as shown, each sub-pixel can be separated from an adjacent sub-pixel in the same pixel by a wall 138a and 138b. Also, in aspects, a pixel wall 138c can separate adjacent pixels. In further aspects, the pixel wall 138c can be wider (i.e., in a dimension perpendicular to the thickness direction 111) than a wall 138a and 138b separating adjacent sub-pixels in the same pixel. As shown, a sub-pixel pitch 132 is defined as an on-center distance between adjacent sub-pixels in the same pixel, and a pixel pitch 136 is the width of a pixel from the center of adjacent pixel walls 138c. In aspects, the sub-pixel pitch 132 can be about 25 μm or more, about 40 μm or more, about 50 μm or more, about 60 μm or more, about 200 μm or less, about 100 μm or less, about 80 μm or less, or about 60 μm or less. In aspects, the sub-pixel pitch 132 can be in a range from about 25 μm to about 200 μm, from about 40 μm to about 100 μm, from about 50 μm to about 80 μm, or any range or subrange therebetween. In aspects, the pixel pitch 136 can be about 75 μm or more, about 100 μm or more, about 150 μm, about 180 μm or more, about 200 μm or more, about 800 μm or less, about 500 μm or less, about 300 μm or less, about 250 μm or less, or about 200 μm or less. In aspects, the pixel pitch 136 can be in a range from about 75 μm to about 800 μm, from about 100 μm to about 500 μm, from about 150 μm to about 300 μm, from about 180 μm to about 250 μm, or any range or subrange therebetween.

Aspects of the disclosure can comprise a consumer electronic product. The consumer electronic product can comprise a front surface, a back surface, and side surfaces. The consumer electronic product can further comprise electrical components at least partially within the housing. The electrical components can comprise a controller, a memory, and a display. The display can be at or adjacent to the front surface of the housing. The display can comprise liquid crystal display (LCD), an electrophoretic displays (EPD), an organic light-emitting diode (OLED) display, or a plasma display panel (PDP). The consumer electronic product can comprise a cover substrate disposed over the display. In aspects, at least one of the display device or the housing comprises the display device 101 and/or anti-sparkle substrate 102 or 202 discussed throughout the disclosure. The consumer electronic product can comprise a portable electronic device, for example, a smartphone, a tablet, a wearable device (e.g., watch), a navigation system, or a laptop. Also, it is to be understood that the display device 101 and/or anti-sparkle substrate 102 or 202 discussed throughout the disclosure can be incorporated into a architectural article, transportation article (e.g., automotive, train, aircraft, sea craft, etc.), or appliance articles including a display.

In aspects, the anti-sparkle substrate 102 or 202 can exhibit sparkle as measured in terms of pixel power deviation reference (PPDr). As used herein, the terms “pixel power deviation referenced” and “PPDr” refer to the quantitative measurement for display sparkle. Unless otherwise specified, sparkle is measured using a SMS-1000 (Display-Messtechnik & Systeme) and a display arrangement that includes an edge-lit liquid crystal display screen (twisted nematic liquid crystal display) having a sub-pixel pitch of 60 μm by 180 μm and pixel pitch of 180 μm and a 1.7 mm thick stack of glass between the display screen and the substrate to be tested. To determine sparkle of a display system or an anti-glare surface that forms a portion of a display system, a screen is placed in the focal region of an “eye-simulator” camera (of the SMS-1000), which approximates the parameters of the eye of a human observer. As such, the camera system includes an aperture (or “pupil aperture”) that is inserted into the optical path to adjust the collection angle of light, and thus approximate the aperture of the pupil of the human eye. In the sparkle measurements described herein, the iris diaphragm is set to the full angle of the device, which subtends an angle of at least 20 milliradians. A first image of the bare display is taken and used as a reference for the image taken with the test sample containing the anti-glare surface. A second image is taken with the substrate positioned between the display and the camera. The boundaries between adjacent pixels are calculated by summing the lines then rows in the image and determining the minima. Total power within each pixel is then integrated and normalized by dividing by the pixel powers from the reference image. The standard deviation of the distribution of pixel powers is then calculated to give the PPDr value. Further information regarding these properties and how these measurements are made can be found in (1) C. Li and T. Ishikawa, “Effective Surface Treatment on the Cover Glass for Auto-Interior Applications,” SID Symposium Digest of Technical Papers, Volume 1, Issue 36.4, pp. 467 (2016); (2) J. Gollier, G. A. Piech, S. D. Hart, J. A. West, H. Hovagimian, E. M. Kosik Williams, A. Stillwell and J. Ferwerda, Display Sparkle Measurement and Human Response, SID Symposium Digest of Technical Papers, Volume 44, Issue 1 (2013); and (3) J. Ferwerda, A. Stillwell, H. Hovagimian and E. M. Kosik Williams, “Perception of sparkle in an anti-reflection and/or an anti-glare display screen,” Journal of the SID, Volume 22, Issue 2 (2014), the contents of which are incorporated herein by reference.

Display “sparkle” is a phenomenon that can occur when anti-glare or light-scattering surfaces are incorporated into a display system. Sparkle is associated with a very fine grainy appearance that can appear to have a shift in the pattern of the grains with changing viewing angle of the display. This type of sparkle is observed when pixelated displays such as LCDs are viewed through an antiglare surface. Such sparkle is of a different type and origin from “sparkle” or “speckle” that has been observed and characterized in projection or laser systems. In aspects, the PPDr value of the anti-sparkle substrate 102 or 202 can be about 3% or less, about 2.7% or less, about 2.5% or less, about 2.2% or less, about 2% or less, about 1.9% or less, about 1.8% or less, about 1% or more, about 1.2% or more, about 1.5% or more, about 1.6% or more, about 1.7% or more, or about 1.8% or more. In aspects, the PPDr value of the anti-sparkle substrate 102 or 202 can be in a range from about 1% to about 3%, from about 1.2% to about 2.7%, from about 1.5% to about 2.5%, from about 1.6% to about 2.2%, from about 1.6% to about 2%, from about 1.7% to about 1.9%, or any range or subrange therebetween. In aspects, a reference sparkle of a display device with another substrate (instead of the anti-sparkle substrate 102 or 202 without the plurality of features 104) can be greater than the spark of the display device 101 by about 20% or more, about 25% or more, about 30% or more, about 33% or more, about 40% or more, or about 50% or more. Reducing a sparkle through the anti-sparkle substrate of the present disclosure and increase a uniformity of light emitted from the display device, as perceived by a viewer of a display device, and/or increase an aesthetic appeal of the resulting display device by reducing the perceived graininess associated with sparkle.

Without wishing to be bound by theory, the plurality of features can locally change a phase of light propagating through a feature of the plurality of features as compared to features propagating through the substrate but not a feature. Changing the phase of light can control destructive interference of light. For example, when the phase change is 180° or π radians (i.e., half the wavelength of light from a whole number (including 0) multiple of the wavelength of light) the light can completely cancel out. The effective phase change can be equal to an integral of a difference in the feature refractive index profile over the depth and the bulk refractive index of the substrate. Consequently, the plurality of features (e.g., including a gradient refractive index, and/or gradient concentration of silver, cesium, and/or rubidium) can function as a diffractive grating. A diffractive grating can produce light beams propagating at various diffraction orders with the angle (θ) between diffraction orders determined by a sub-pixel pitch (p), a spacing between the pixelated display and the plurality of features (L), a refractive index of the substrate (n), the wavelength of light (λ), and the feature pitch (Λ). For example, the relationship: λ=λ/(n*sin(θ)), where tan(θ)=p/L. The diffraction induced by the plurality of features can reduce sparkle by reducing a contrast between bright spots (e.g., where light from a pixel would naturally be perceived by a user) and spaces therebetween since the diffractive orders (e.g., principally the first diffractive order) can increase the intensity of light therebetween. For example, the diffractive order can correspond to virtual images that can be perceived by a user of the display device as corresponding to the other sub-pixels of the pixel and/or other sub-pixels to provide a more uniform brightness (e.g., light intensity) of the corresponding light wavelength. Further, the gradient concentration profile and/or gradient refractive index profile of a feature of the plurality of features (e.g., as compared to a step profile of concentration and/or refractive index) can reduce a reflection (e.g., specular reflection) of ambient light incident on the second major surface and through the substrate that could otherwise be perceived by a user of the display device as washing out the display, additional bright spots, and/or refracted rainbows that can be distracting.

In aspects, the anti-sparkle substrate 102 or 202 can comprise a reflectance of light incident on the second major surface 105 or 205 reflecting from the plurality of features extending from the opposite, first major surface 107. Unless otherwise specified, reflectance refers to average reflectance that is calculated by averaging reflectance measurements taken at whole number wavelengths from about 400 nm to about 700 nm. As used herein, reflectance is measured in accordance with ASTM F1252-21 at an angle of 8° relative to a direction normal to the surface. Throughout the disclosure, a direction normal to the second major surface 105 is defined relative to a first plane, where the first plane is taken as a least-squares fit to the portions of the first major surface 107 excluding any texturing. If the substrate is non-planar, the direction normal to the textured surface is relative to a plane fit to the 50 μm×50 μm region of the textured surface (excluding the plurality of pits) where the light is incident. In aspects, the reflectance (e.g., average reflectance) can be about 2% or less, about 1% or less, about 0.5% or less, about 0.2% or less, about 0.1% or less, about 0.05% or less, about 0.02% or less, about 0.01% or less, about 0.005% or less, about 0.002% or less, or about 0.001% or less.

Aspects of methods of making the anti-sparkle substrate 102 and/or 202 and/or display device 101 illustrated in FIGS. 1-2, in accordance with aspects of the disclosure, will be discussed with reference to the flow chart in FIG. 7 and example method steps illustrated in FIGS. 8-11.

In a first step 701 of methods of the disclosure, as shown in FIG. 8, methods can start with providing a substrate 103. In aspects, the substrate 103 may be provided by purchase or otherwise obtaining a substrate or by forming the substrate. In aspects, the substrate 103 can comprise a glass-based material or a ceramic-based material. In further aspects, glass-based substrates can be provided by forming them with a variety of ribbon forming processes, for example, slot draw, down-draw, fusion down-draw, up-draw, press roll, redraw or float. In further aspects, glass-based substrates comprising ceramic crystals can be provided by heating a glass-based substrate to crystallize one or more ceramic crystals. In aspects, the second major surface 205 can comprise a textured surface 206 at the end of step 701, although the second major surface may not be textured (either by the end of step 701 or at any point in the methods in some aspects).

After step 701, in aspects, as shown in FIG. 8, methods can proceed to step 703 comprising texturing the second major surface 205 to form the textured surface 206. In aspects, the texturing can comprise abrading the surface, for example, sandblasting the second major surface. Alternatively or additionally, in aspects, the texturing can comprise contacting the second major surface with an etchant. At the end of step 703 the textured surface 206 can comprise any one of the corresponding aspects discussed above with reference to the textured surface 206 and/or the exterior surface 145 of the anti-glare layer 143.

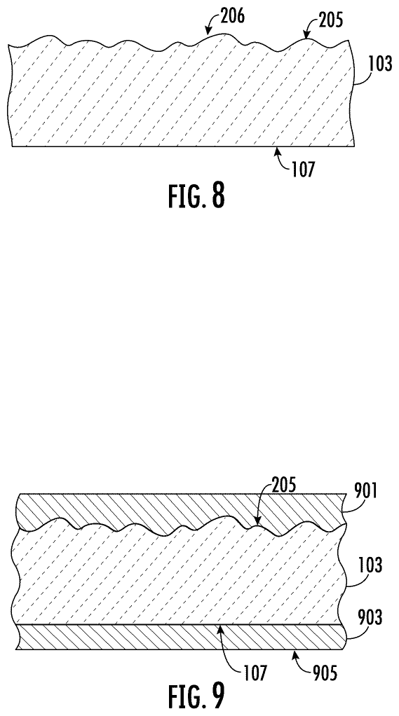

After step 701 or 703, as shown in FIG. 9, methods can proceed to step 705 comprising disposing a mask (e.g., first mask 903, second mask 901) on at least the first major surface 107 of the substrate 103. In aspects, as shown, the disposing can comprise disposing a first mask 903 on the first major surface 107 of the substrate 103. In aspects, as shown, the disposing can additionally comprise disposing a second mask 901 on the second major surface 205 (e.g., textured surface). The mask (e.g., first mask 903, second mask 901) can comprise a material that can resist chemicals used in step 707 and/or reduces or blocks the diffusion of the ions present in step 705. In aspects, the mask can comprise a photosensitive material (as discussed in the next paragraph).

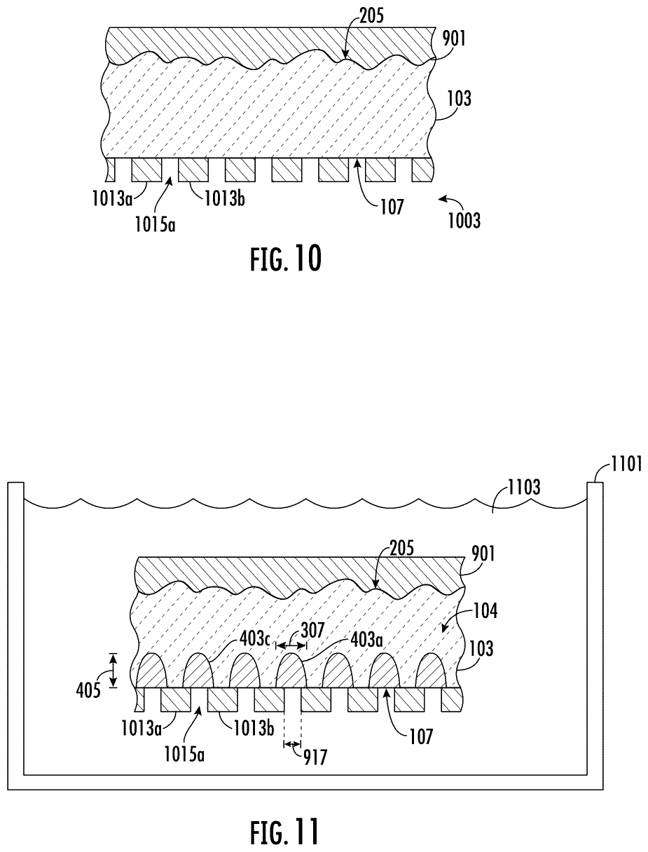

After step 705, as shown in FIG. 10, methods can proceed to step 707 comprising patterning the first mask 903. In aspects, as shown, the patterning can remove material in regions 1015a to expose portions of the first major surface 107. In aspects, as shown, the patterning can form a patterned mask 1003 with mask portions 1013a and 1013b separated by the regions 1015a where the mask is removed. In aspects, the patterning can comprise a photolithography process. For example, in further aspects, a photosensitive material can be disposed on the first mask; portions of the photosensitive material can be selectively exposed to light; and portions of the photosensitive material and corresponding portions of the mask can be removed (e.g., using wet etching or dry etching) to form the patterned mask 1003. Alternatively, for example, the first mask 903 can comprise a photosensitive material; portions of the photosensitive material (e.g., first mask) can be selectively exposed to light; and portions of the first mask can be removed (e.g., using wet etching or dry etching) to form the patterned mask 1003. In further aspects, the first mask can be positively photosensitive; alternatively, the first mask can be negatively photosensitive. Throughout the disclosure, a positive photoresist refers to a material where a portion exposed to light in a wavelength range (e.g., ultraviolet) can be more easily removed (e.g., using an etchant) than a portion of the material not exposed to the light. Throughout the disclosure, a negative photoresist refers to a material where a portion exposed to light in a wavelength range (e.g., ultraviolet) is more resistant (e.g., etches slower) to removal (e.g., using an etchant) than a portion of the material not exposed to the light. In aspects, the regions 1015a can comprise a polygonal (e.g., hexagonal) cross-sectional shape, a curved (e.g., oval, circular) cross-sectional shape, or a curvilinear shape. In aspects, each of the regions 1015a can comprise substantially the same cross-sectional shape and/or cross-sectional area.

After step 701 or 707, as shown in FIG. 11, methods can proceed to step 709 comprising exposing a plurality of portions (e.g., corresponding to regions 1015a) of the first major surface 107 to a source (e.g., solution 1103) of one or more of silver ions, rubidium ions, cesium ions, or combinations thereof to form the plurality of features 104. In aspects, as shown, the source comprises a solution 1103 contained in a bath 1101, and the exposing comprises immersing at least the plurality of portions (e.g., corresponding to region 1015a) and the patterned mask in the solution 1103. In aspects, the solution 1103 can comprise a source of silver ions (e.g., silver nitrate), and the exposing exposes the plurality of portions (e.g., corresponding to regions 1015a) to silver ions.

In aspects, the solution can comprise a molten salt solution. In further aspects, the molten salt solution can comprise a total amount of silver ions, rubidium ions, and cesium ions, as a wt % of the solution, can be about 0.1 wt % or more, about 0.2 wt % or more, about 0.5 wt % or more, about 1 wt % or more, about 2 wt % or more, about 5 wt % or more, about 20 wt % or less, about 15 wt % or less, about 10 wt % or less, about 8 wt % or less, about 5 wt % or less, about 3 wt % or less, about 2 wt % or less, or about 1 wt % or less, for example, in a range from about 0.1 wt % to about 20 wt %, from about 0.2 wt % to about 15 wt %, from about 0.5 wt % to about 10 wt %, from about 1 wt % to about 8 wt %, from about 2 wt % to about 5 wt %, or any range or subrange therebetween. In further aspects, the molten salt solution can comprise an amount of silver ions within one or more of the ranges mentioned in the previous sentence. In aspects, the exposing can occur for about 1 minute or more about 2 minutes or more, about 5 minutes or more, about 10 minutes or more, about 15 minutes or more, about 20 minutes or more, about 30 minutes or more, about 1 hour or more, about 4 hours or less, about 2 hours or less, about 1 hours or less, about 45 minutes or less, about 30 minutes or less, about 20 minutes or less, about 15 minutes or less, about 10 minutes or less, about 8 minutes or less, or about 5 minutes or less. In aspects, the exposing can occur for a period of time in a range from about 1 minute to about 4 hours, from about 2 minutes to about 2 hours, from about 5 minutes to about 1 hour, from about 10 minutes to about 45 minutes, from about 15 minutes to about 30 minutes, or any range or subrange therebetween. In aspects, the exposing can occur for less than 15 minutes, for example, in a range from about 1 minute to about 10 minutes, from about 2 minutes to about 10 minutes, from about 2 minutes to about 8 minutes, from about 5 minutes to about 8 minutes, or any range or subrange therebetween.

As shown in FIG. 11, a feature 403c of the plurality of feature 104 formed in step 711 includes the portion of the first major surface 107 of a corresponding region of the regions 1015a where the mask is removed. In aspects, as shown in FIG. 11, an exposed width 917 of the portion of the first major surface 107 exposed by a region of the regions 1015a from step 709 can be less than or equal to the maximum dimension 307 of the feature 303a formed in step 711. In further aspects, as shown, the exposed width 917 can be less than the maximum dimension 307. Without wishing to be bound by theory, the diffusion of ions (e.g., silver, cesium, rubidium) can occur in all directions (e.g., in the thickness direction 111 and perpendicular to the thickness direction), which can produce a maximum dimension of a feature that is greater than the corresponding exposed width.

After step 711, methods can proceed to step 713 comprising assembling a display device (see FIG. 1) comprising the anti-sparkle substrate 102 or 202. In aspects, as shown in FIG. 1, an anti-glare layer 143 comprising the textured, exterior surface 145 can be disposed over the second major surface 105. In aspects, as shown in FIG. 1, an optical stack 113 and/or a pixelated display 133 can be disposed over the first major surface 107 of the anti-sparkle substrate 102 or 202. In aspects, as described above, the anti-sparkle substrate 102 or 202 can be used in conjunction with a plurality of light-emitting diodes (e.g., LED, OLED), for example, in a pixelated display, as part of a display device and/or a consumer electronic device. After step 709, 711, or 713, methods can be complete upon reaching step 715.

In aspects, methods of making an anti-sparkle substrate 102 and/or 202 and/or display device 101 in accordance with aspects of the disclosure can proceed along steps 701, 703, 705, 707, 709, 711, 713, and 715 of the flow chart in FIG. 7 sequentially, as discussed above. In aspects, arrow 702 can be followed from step 701 to step 705, for example, when the second major surface 205 comprises a textured surface 206 by the end of step 701 or when the second major surface 205 is not to be textured (either by the end of step 701 or at any point in the methods in some aspects). In aspects, arrow 704 can be followed from step 701 to step 709, for example, when there is a patterned mask on the substrate 103 is ready to be etched at the end of step 701. In aspects, arrow 706 can be followed from step 709 to step 715, for example, if methods are complete at the end of step 709. In aspects, arrow 708 can be followed from step 711 to step 715, for example, if methods are complete at the end of step 715. Any of the above options may be combined to make a color converter sheet in accordance with aspects of the disclosure.

### EXAMPLES

Various aspects will be further clarified by the following examples. Results for Examples 1-4 are based on a finite-difference time-domain (FDTD) modelling simulation of light interacting with the corresponding Example. Results for Comparative Examples AA-DD and Example 5 are from laboratory measurements of physical samples.

For Examples 1-4, a plurality of features extending from the first major surface of a glass-based substrate was simulated, where the bulk refractive index of the glass-based substrate 1.50, each feature of the plurality of features comprised the same refractive index profile in a given Example, and the refractive index of the plurality of features varied from Example 1 to Example 4. The feature refractive index (“|Anl”) for Examples 1-4 was set as 0.01, 0.03, 0.07, and 0.10, respectively, at the first major surface the maximum dimension of the features was 12.6 μm, and the refractive index profile exponentially decayed (similar to that shown in FIG. 5 and measured for Example 5, as described below) from the feature refractive index at the surface to be equal to the bulk refractive index (1.5) at the maximum dimension. Comparative Example CC corresponds to a simulation of the glass-based substrate with a diffractive grating with a step refractive index (as opposed to the gradient refractive index of the plurality of features) of 1.58 disposed on the first major surface (similar to Comparative Example AA). Comparative Example DD was the same as Comparative Example CC except that the diffractive grating comprised a step refractive index of 1.8. Light comprising a wavelength of 532 nm being transmitted through the first major surface to the second major surface was simulated to determine sparkle. For Examples 1-4, the anti-glare surface (i.e., first major surface) was simulated using the same pattern of randomly positioned cylindrical objects with a thickness of 0.133 μm and a diameter of 50 μm with the spacing between adjacent objects of 10 μm and an average spacing between adjacent objects of 30 μm.

Comparative Examples AA-BB and Example 5 use a glass-based substrate (Composition A comprising approximately 64.5 mol % SiO₂, 15.9 mol % Al₂O₃, 6.3 mol % Li₂O, 10.9 mol % Na₂O, 1.2 mol % ZnO, and 1.1 mol % P₂O₅). The second major surface of Comparative Examples AA-BB and Example 5 were sandblasted followed by etching with HF to achieve a textured surface and a haze of 10%. Comparative Example BB comprised a glass-based substrate with the textured surface “as-is” (i.e., without the plurality of features or a commercial anti-sparkle grating). Comparative Example AA comprised the glass-based substrate of Comparative Example BB with the addition of OCA Antisparkle Film (3M) comprising high refractive index film gratings sandwiched between layers of an optically clear adhesive that was disposed on the second major surface of the glass-based substrate.

FIGS. 12-15 schematically represent sparkle measurements for simulated Examples 1-4. The horizontal axis 1201 corresponds to the depth of the simulated features in micrometers (μm), the vertical axis 1203, 1303, 1403, or 1503 corresponds to the simulated sparkle (PPDr %), and the curve 1205, 1305, 1405, and 1505. As shown in FIG. 12, (at a depth of 0) a substrate without any features has a sparkle of 4.2% PPDr, which also corresponds to the simulation result for Comparative Example CC. For Example 1, curve 1205 shows that the sparkle decreases as the depth of the features increases, with a sparkle of slightly more than 3% PPDr sparkle for a depth of 15 μm. In FIGS. 13-15, line 1309 is at a sparkle of 3% PPDr, which indicates whether portions of curves 1305, 1405, and 1505 can improve of the lowest sparkle shown in FIG. 12 for Example 1. As shown in FIGS. 13-15, curves 1305, 1405, and 1505 do achieve lower sparkle than 3% PPDr. For example, Example 2 with a refractive index difference of 0.03 is able to achieve a sparkle less than 3% for depths between about 5 μm and about 13 μm with a minimum sparkle of about 2% PPDr occurring for features with a depth of about 10 μm, as shown by point 1307 in FIG. 13. As discussed above, a minimum sparkle is expected to occur when the integral of a difference in the feature refractive index profile over the depth and the bulk refractive index of the substrate is equal to half of the wavelength of the light transmitted therethrough or half of the wavelength beyond a whole number multiple of the wavelength. Indeed, point 1307 corresponds to an integral of about 266 nm, which is half of the 532 nm wavelength of the simulated light. The minima at point 1307 corresponds to a reduction of more than 50% compared to the 4.2% PPDr without any features (depth=0 μm in FIG. 13).

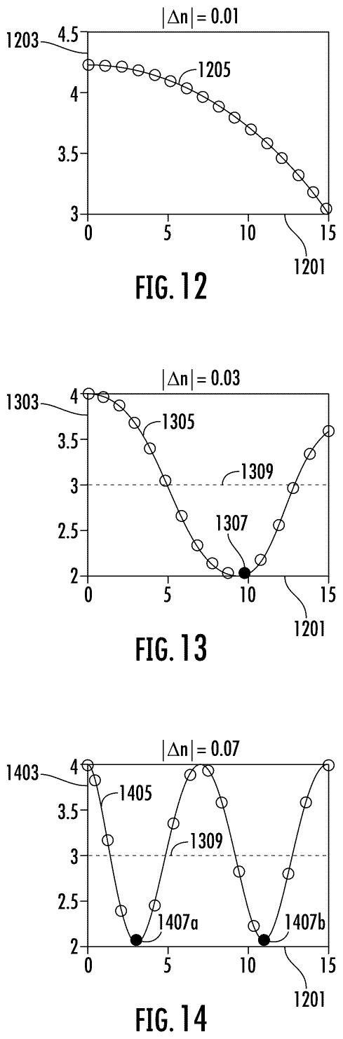

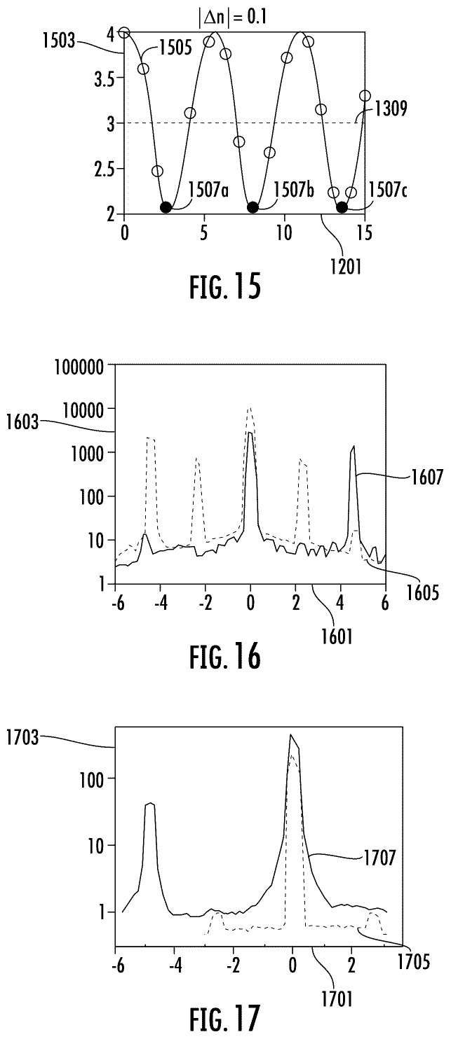

As shown in FIG. 14, Example 3 has two local minima 1407a and 1407b in curve 1405 at a depth of about 3 μm and about 11 μm that also correspond to an integral of about 266 nm and 798 nm (266 nm beyond 532 nm). For Example 3, curve 1405 is below line 1309 for depths from about 1.5 μm to about 5 μm and from about 9 μm to about 13.5 μm. As shown in FIG. 15, Example 4 has three local minima 1507a, 1507b, and 1507c at a depth of about 2.5 μm, about 8 μm, and about 13.5 μm that correspond to half of the wavelength (266 nm) beyond whole number (including 0) multiples of the wavelength (i.e., 266 nm, 798 nm, and 1330 nm). For Example 4, curve 1505 is below line 1309 for depths between about 2 μm and about 4 μm, between about 7 μm and about 9 μm, and between about 12.5 μm and about 15 μm. Overall, Examples 1-4 demonstrate that a feature refractive index greater than the substrate refractive index by more than 0.01 (e.g., about 0.02 or more, about 0.03 or more) can achieve sparkle less than 3% PPDr (e.g., less than or equal to 2.5% PPDr and/or less than or equal to 2% PPDr) for features with a reasonable depth (e.g., about 15 μm or less or from about 2 μm to about 12 μm). As the difference between the feature refractive index and the substrate refractive index increases, the number of minima increases and the depth where the first minima occurs decreases. At the same time, a sensitivity of the sparkle to changes in feature depth decreases as the difference between the feature refractive index and the substrate refractive index decreases (but is still greater than 0.01 or greater than or equal to 0.02), which increases a variability in feature depth that can achieve a predetermined sparkle threshold. Consequently, a difference between the feature refractive index and the substrate refractive index can balance a feature depth for achieving a predetermined sparkle threshold and acceptable process variability to achieve the predetermined sparkle threshold for a difference from about 0.01 to about 0.10, from about 0.02 to about 0.10, from about 0.03 to about 0.10, or any of the corresponding ranges discussed above.

The reflectance of light incident on the second major surface reflecting from the first major surface and any associated features or diffractive grating was simulated for Example 4 (with a depth of about 2.5 (see local minima 1507a in FIG. 15)) and Comparative Examples CC-DD. This corresponds to the reflection of ambient light off of the first major surface towards a user of a display device. Comparative Example CC comprised a simulated reflectance of 0.01% off of the first major surface and the diffractive grating. Comparative Example DD comprised a simulated reflectance of 2.2%. Example 4 (as described above in this paragraph) comprised a simulated reflectance of 0.00033% off of the first major surface and plurality of features. This demonstrates that the plurality of features does not increase back reflection of light, and, in fact, may decrease back reflection by about 30 times or more relative to Comparative Example CC (and more than 1,000 times relative to Comparative Example DD).

For Example 5, the plurality of features were formed by (1) disposing a thin-film mask with a thickness of more than 100 nm on all surfaces of the glass-based substrate with the textured surface; (2) patterning the thin-film mask disposed on the second major surface using photolithography to expose circular portions with a diameter of 6 μm of the first major surface; (3) exposing the exposed circular portions to a source of silver ions by immersing the glass-based substrate in a 20 wt % AgNO₃ solution maintained at a temperature of 300° C. for 200 seconds; and (4) removing the thin-film mask. The features of the plurality of features were substantially uniform with a maximum dimension (on the second major surface) of 12.6 μm and a feature pitch of 17 μm between adjacent features in a hexagonal close-packed array, which was verified using scanning electron microscope-energy dispersive X-ray (SEM-EDS) of the first major surface. This corresponds to a percentage of a total feature surface area of the plurality of features on the first major surface to a total surface area of the first major surface of about 50%. A reactive index profile of the feature (see FIG. 5 and associated discussion above) was measured using a prism coupling measurement technique with a wavelength of 589 nm using polarized light with the results processed using the inverse Wentzel-Kramers-Brillouin (iWKB) method to extract refractive index information. The measured refractive index profile of the feature had a maximum refractive index at the first major surface of about 1.585, a refractive index of about 1.52 at a depth of about 8 μm from the first major surface, and a depth of the feature was about 15 μm.

For the sparkle measurements of Comparative Examples AA-BB and Example 5, a 1 mm stack of glass-based substrates (Composition A) interleaved with baby oil was positioned between the glass-substrate mentioned above (and any diffractive grating) and a pixelated display with a resolution of 63 pixels per centimeter (140 pixels per inch) corresponding to sub-pixel pitch of 60 μm. The sparkle was measured using the SMS-1000, as described above. Comparative Example BB had an experimentally measured sparkle of 5.8% PPDr. Example 5 had an experimentally measured sparkle of 4.0% PPDr.

For Comparative Example AA and Example 5, a Bi-Directional Transmittance Distribution Function (BDTF) and a Bi-Directional Reflectance Distribution Function (BRDF) are measured using a Complete Angle Scattering Instrument (CASI) goniometer (available from Scatter Works, Inc.) with light comprising a wavelength of 633 nm. As used herein, the BTDF is measured by transmitting light that is incident on the first major surface at an incidence angle θᵢ of 0° relative to a direction normal to the first major surface, measuring the distribution of light flux as a function of a transmitted angle θ_{T} that is measured relative to a direction normal to the second major surface. Light flux refers to the light intensity of light (e.g., in lumens) per unit area (e.g., meters squared) at a location that the area is centered. The Bi-Directional Transmittance Distribution Function (BTDF) corresponds to a ratio of transmitted light to incident light. As used herein, the BRDF is measured by impinging light on the second major surface at an incidence angle θᵢ of 15° relative to a direction normal to the second major surface, measuring the distribution of light flux as a function of a reflectance angle θ_{R} that is measured relative to a direction normal to the second major surface. The Bi-Directional Reflectance Distribution Function (BRDF) corresponds to a ratio of reflected light to incident light, and the ccBRDF(θᵢ, θ_{R})=BRDF(θᵢ, θ_{R})*cos(θ_{R}).

FIG. 16 presents the BTDF function for Example 5 (curve 1605) and Comparative Example AA (curve 1607) with the horizontal axis 1601 corresponding to the transmitted angle θ_{T} in degrees and the vertical axis 1603 corresponding to the intensity of the BTDF curve in inverse steradians (sr⁻¹) on a logarithmic scale. Both Example 5 and Comparative Example AA show a peak at 0° corresponding to light directly transmitted therethrough with smaller peaks corresponding to higher diffraction orders. For Comparative Example AA, a ratio of the intensity of first-order diffraction peak (at ±4.5°) to the intensity of the zeroth order diffraction peak (at 0°) is 38.6%. For Example 5, the ratio of the intensity of first-order diffraction peak (at ±2.5°) to the intensity of the zeroth order diffraction peak (at 0°) is 8.5%. As noted for Example 4 (see FIG. 15), one of the minima in sparkle occurs around a depth of about 13.5 μm rather than the 15 μm for Example 5. Consequently, it is believed that the ratio can be improved by selecting a feature depth closer to the minima suggested by the simulations discussed above, which would produce a more uniform transmitted light intensity and decreased sparkle.

FIG. 17 presents the BRDF function for Example 5 (curve 1705) and Comparative Example AA (curve 1707) with the horizontal axis 1701 corresponding to the reflected angle θ_{R} in degrees relative to a specular reflection and the vertical axis 1703 corresponding to the intensity of the BRDF curve in inverse steradians (sr⁻¹) on a logarithmic scale. Both Example 5 and Comparative Example AA show a peak at 0° corresponding to light specularly reflected off of the first major surface, plurality of features, and/or diffractive grating with smaller peaks corresponding to higher diffraction orders. For Comparative Example AA, a ratio of the intensity of first-order diffraction peak (at ±4.8°) to the intensity of the zeroth order diffraction peak (at 0°) is 10.5%. For Example 5, the ratio of the intensity of first-order diffraction peak (at ±2.5°) to the intensity of the zeroth order diffraction peak (at 0°) is 0.23%. The reduced ratio for Example 5 relative to Comparative Example AA indicates that plurality of features of Example 5 are “anti-reflective” relative to Comparative Example AA and would be expected to reduce an appearance of reflected “rainbows” of ambient light perceived by a user of a display device by more than 40 times.

The above observations can be combined to provide an anti-sparkle substrate and display devices including anti-sparkle substrates that can reduce a sparkle thereof by providing a plurality of features as part of the anti-sparkle substrate. The plurality of features can be integral to the anti-sparkle substrate, which can simplify assembly and/or alignment of elements in a resulting display device. Providing the anti-sparkle substrate as a glass-based substrate and/or ceramic-based substrate can facilitate the formation of the plurality of features (e.g., introduction of one or more of silver ions, cesium ions, rubidium ions, or combinations thereof), decrease a color shift of the display device (e.g., as a result of aging), increase a damage resistance, and/or increase a flexibility of the display device.

Reducing a sparkle through the anti-sparkle substrate of the present disclosure and increase a uniformity of light emitted from the display device, as perceived by a viewer of a display device, and/or increase an aesthetic appeal of the resulting display device by reducing the perceived graininess associated with sparkle. Without wishing to be bound by theory, the plurality of features can locally change a phase of light propagating through a feature of the plurality of features as compared to features propagating through the substrate but not a feature. Changing the phase of light can control destructive interference of light. For example, when the phase change is 180° or π radians (i.e., half the wavelength of light from a whole number (including 0) multiple of the wavelength of light) the light can completely cancel out. The effective phase change can be equal to an integral of a difference in the feature refractive index profile over the depth and the bulk refractive index of the substrate. Consequently, the plurality of features (e.g., including a gradient refractive index, and/or gradient concentration of silver, cesium, and/or rubidium) can function as a diffractive grating. A diffractive grating can produce light beams propagating at various diffraction orders with the angle (θ) between diffraction orders determined by a sub-pixel pitch (p), a spacing between the pixelated display and the plurality of features (L), a refractive index of the substrate (n), the wavelength of light (λ), and the feature pitch (Λ). For example, the relationship: Λ=λ/(n*sin(θ)), where tan(θ)=p/L. The diffraction induced by the plurality of features can reduce sparkle by reducing a contrast between bright spots (e.g., where light from a pixel would naturally be perceived by a user) and spaces therebetween since the diffractive orders (e.g., principally the first diffractive order) can increase the intensity of light therebetween. For example, the diffractive order can correspond to virtual images that can be perceived by a user of the display device as corresponding to the other sub-pixels of the pixel and/or other sub-pixels to provide a more uniform brightness (e.g., light intensity) of the corresponding light wavelength. Further, the gradient concentration profile and/or gradient refractive index profile of a feature of the plurality of features (e.g., as compared to a step profile of concentration and/or refractive index) can reduce a reflection (e.g., specular reflection) of ambient light incident on the second major surface and through the substrate that could otherwise be perceived by a user of the display device as washing out the display, additional bright spots, and/or refracted rainbows that can be distracting.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements, or steps of particular aspects may be disclosed using the transitional phrase “comprising,” it is to be understood that alternative aspects, including those that may be described using the transitional phrases “consisting of” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed is:

1. An anti-sparkle substrate comprising:
a plurality of features extending from a first major surface of the anti-sparkle substrate to a depth, a feature of the plurality of features comprising a feature concentration of one or more of silver, rubidium, or cesium, the feature concentration is non-zero at the first major surface, and the feature concentration is greater than a concentration of one or more of silver, rubidium, or cesium of a region of the first major surface excluding the plurality of features.

2. The anti-sparkle substrate of claim 1, wherein a feature refractive index of the feature at the first major surface is greater than a substrate refractive index of the region of the first major surface excluding the plurality of features by from 0.01 to 0.12.

3. The anti-sparkle substrate of claim 2, wherein the feature refractive index is greater than the substrate refractive index by from 0.03 to 0.10.

4. The anti-sparkle substrate of claim 2, wherein the feature of the plurality of features comprising a gradient refractive index profile extending from the first major surface to the depth.

5. The anti-sparkle substrate of claim 1, wherein a concentration profile of the feature is a gradient from the feature concentration at the first major surface to a bulk concentration at the depth, the feature concentration is greater than the bulk concentration, and the concentration profile and the bulk concentration is of one or more of silver, rubidium, or cesium.

6. The anti-sparkle substrate of claim 2, wherein the feature refractive index is in a range from about 1.55 to about 1.60.

7. The anti-sparkle substrate of claim 3, wherein an integral of a difference in the gradient refractive index profile of the feature from the first major surface to the depth and a substrate refractive index profile of a portion excluding the plurality of features is in a range from about 200 nanometers to about 350 nanometers.

8. The anti-sparkle substrate of claim 1, wherein the depth is in a range from about 8 micrometers to about 30 micrometers.

9. The anti-sparkle substrate of claim 1, wherein a maximum dimension of the feature on the first major surface is in a range from about 5 micrometers to about 20 micrometers.

10. The anti-sparkle substrate of claim 1, wherein a spacing between an adjacent pair of features of the plurality of features is in a range from about 8 micrometers to about 30 micrometers, and the spacing is measured from a center of a first feature of the adjacent pair of features to a center of a second feature of the adjacent pair of features.

11. The anti-sparkle substrate of claim 1, wherein a percentage of a total feature surface area of the plurality of features on the first major surface to a total surface area of the first major surface is in a range from about 35% to about 75%.

12. The anti-sparkle substrate of claim 1, wherein the plurality of features are integral to the anti-sparkle substrate.

13. The anti-sparkle substrate of claim 1, wherein a reflectance of light incident on a second major surface of the anti-sparkle substrate opposite the first major surface is less than 0.001%.

14. The anti-sparkle substrate of claim 1, wherein a second major surface of the anti-sparkle substrate comprises a textured surface, the second major surface opposite the first major surface.

15. The anti-sparkle substrate of claim 1, wherein the anti-sparkle substrate exhibits a sparkle, as measured by pixel power deviation reference (PPDr), in a range from about 1% to 3%.

16. A display device comprising:
a pixelated display unit;
an antiglare layer; and
the anti-sparkle substrate of claim 1, positioned between the pixelated display unit and the antiglare layer.

17. The display device of claim 16, wherein the display device exhibits a sparkle, as measured by pixel power deviation reference (PPDr), in a range from about 1% to 3%.

18. The display device of claim 16, wherein a reference sparkle of another display device with another substrate instead of the anti-sparkle substrate without the plurality of features is greater than the sparkle of the display device by about 30% or more.

19. A method of making an anti-sparkle substrate comprising:
exposing a plurality of portions of a first major surface of a substrate to a source of one or more of silver ions, rubidium ions, or cesium ions to form a plurality of features in the substrate, wherein the plurality of features include the plurality of portions, and the plurality of features extend from the first major surface of a depth.

20. The method of claim 19, wherein the exposing comprises contacting the plurality of portions with a molten salt solution comprising from 0.1 wt % to 20 wt % of one or more of silver nitrate, rubidium nitrate, or cesium nitrate.
